(19) United States
(12) Patent Application Publication
(10) Pub. No.: US 2016/0104673 A1
(43) Pub. Date: Apr. 14, 2016

(54) FIN-SHAPED FIELD-EFFECT TRANSISTOR WITH A GERMANIUM EPITAXIAL CAP AND A METHOD FOR FABRICATING THE SAME

(71) Applicant: UNITED MICROELECTRONICS CORP., Hsin-Chu City (TW)

(72) Inventor: Yu-Cheng Tung, Kaohsiung City (TW)

(21) Appl. No.: 14/510,119

(22) Filed: Oct. 9, 2014

(51) Int. Cl. H01L 23/522; H01L 29/66; H01L 21/768; H01L 29/78; H01L 23/532

(52) U.S. Cl. CPC H01L 23/5226; H01L 29/7851; H01L 23/53209; H01L 21/76802; H01L 21/76877; H01L 29/66795

(57) ABSTRACT

A FinFET includes a fin-shaped structure, a gate structure, an epitaxial layer, an interlayer dielectric layer, an opening, a germanium cap and a contact plug. The fin-shaped structure is disposed on the substrate. The gate structure covers a portion of the fin-shaped structure. The epitaxial layer is disposed on the fin-shaped structure adjacent to the gate structure. The interlayer dielectric layer covers the gate structure and the epitaxial layer. The opening is in the interlayer dielectric layer. The germanium cap fills the bottom of the opening and has a germanium concentration in excess of 50 atomic %. The contact plug is disposed on the germanium cap in the opening.

### BACKGROUND OF THE INVENTION

1. Field of the Invention

The present invention relates generally to the field of the fin-shaped field-effect transistor, and more particularly to a fin-shaped field-effect transistor with a germanium epitaxial cap and a method for fabricating the same.

2. Description of the Prior Art

In recent years, as various kinds of consumer electronic products have continuously improved and been miniaturized, the size of semiconductor components has reduced accordingly, in order to meet requirements of high integration, high performance, and low power consumption.

With the trend in the industry being towards scaling down the size of the metal oxide semiconductor transistors (MOS), three-dimensional or non-planar transistor technology, such as fin field effect transistor technology (FinFET) has been developed to replace planar MOS transistors. Since the three-dimensional structure of a FinFET increases the overlapping area between the gate and the fin-shaped structure of the silicon substrate, the channel region can therefore be more effectively controlled. This way, the drain-induced barrier lowering (DIBL) effect and the short channel effect are reduced. The channel region is also longer for an equivalent gate length, thus the current between the source and the drain is increased. In addition, the threshold voltage of the fin FET can be controlled by adjusting the work function of the gate.

In the conventional process for fabricating FinFETs, formation of a silicon cap is typically performed as soon as epitaxial layers are formed. However, this approach often causes bump issues on the surface of the polysilicon gate. Moreover, during the fabrication of salicides, problems such as encroachment is caused on the liner between the gate and the spacer as a result of wet clean, which further results in nickel silicide piping. In addition, the external resistance of the S/D regions is still high even though the silicon cap is used in the FinFETs.

Hence, how to improve the current process to resolve the aforementioned issues has become an important task in this field.

### SUMMARY OF THE INVENTION

According to a preferred embodiment of the present invention, a fin-shaped field-effect transistor (FinFET) is disclosed. The FinFET includes a fin-shaped structure, agate structure, an epitaxial layer, an interlayer dielectric layer, an opening, a germanium cap and a contact plug. The fin-shaped structure is disposed on the substrate. The gate structure covers a portion of the fin-shaped structure. The epitaxial layer is disposed on the fin-shaped structure adjacent to the gate structure. The interlayer dielectric layer covers the gate structure and the epitaxial layer. The opening is in the interlayer dielectric layer. The germanium cap fills the bottom of the opening and has a germanium concentration in excess of 50 atomic %. The contact plug is disposed on the germanium cap in the opening.

According to another embodiment of the present invention, a method for fabricating a FinFET is disclosed. The method includes the following steps: providing a substrate; forming a fin-shaped structure on the substrate; forming agate structure on the fin-shaped structure; forming an epitaxial layer in the fin-shaped structure adjacent to the gate structure; forming an interlayer dielectric layer on the gate structure and the epitaxial layer; forming an opening in the interlayer dielectric layer; forming a germanium cap at the bottom of the opening, wherein the germanium cap has a germanium concentration in excess of 50 atomic %; and forming a contact plug on the germanium cap in the opening.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-14 illustrate a method for fabricating FinFET according to a preferred embodiment of the present invention.

### DETAILED DESCRIPTION

In the following description, numerous specific details are given to provide a thorough understanding of the invention. It will, however, be apparent to one of ordinary skill in the art that the invention may be practiced without these specific details. Furthermore, some well-known system configurations and process steps are not disclosed in detail.

The drawings showing embodiments of the apparatus are not to scale and some dimensions are exaggerated for clarity of presentation. Also, where multiple embodiments are disclosed and described as having some features in common, like or similar features will usually be described with same reference numerals for ease of illustration and description thereof.

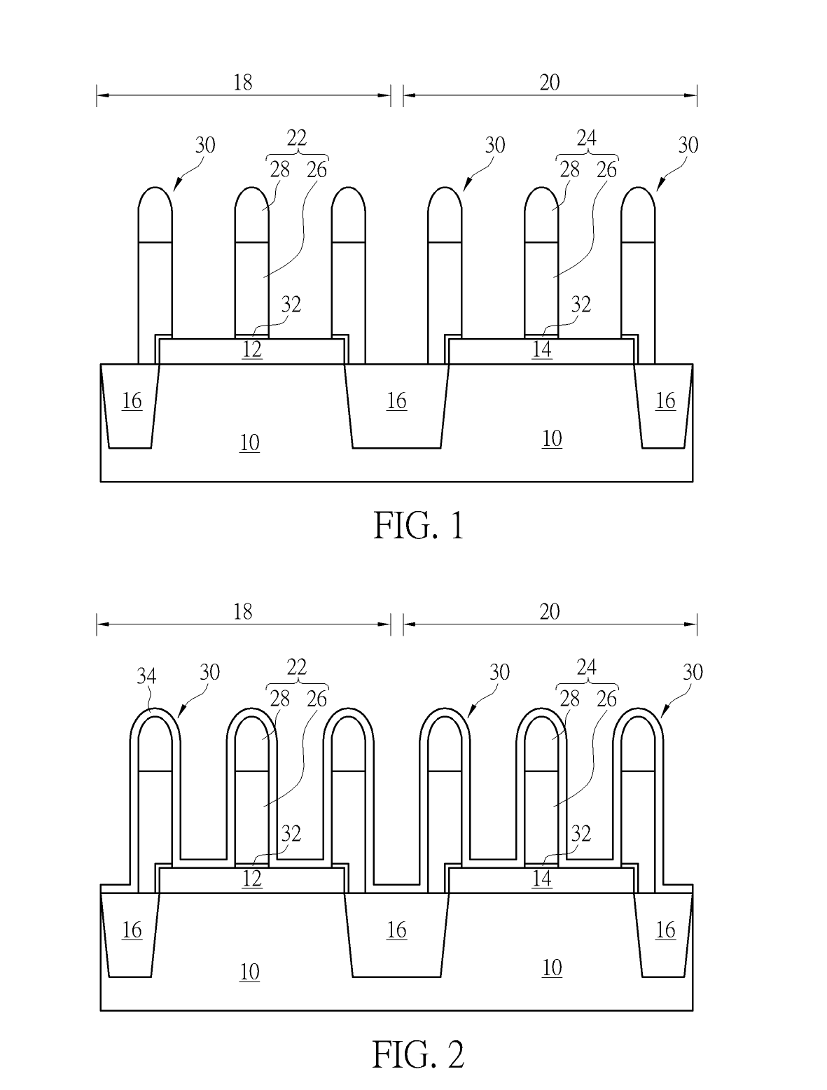

FIGS. 1-14 illustrate a method for fabricating a semiconductor device, such as a FinFET according to a preferred embodiment of the present invention. As shown in FIG. 1, a substrate 10, such as a silicon substrate or a silicon-on-insulator (SOI) substrate is provided. A first transistor region, such as a PMOS region 18 and a second transistor region, such as a NMOS region 20 are defined on the substrate 10.

At least a first fin-shaped structure 12, at least a second fin-shaped structure 14, and an insulating layer 16 are formed on the substrate 10. The bottom of the fin-shapes structures 12, 14 is preferably enclosed by the insulating layer 16, such as silicon oxide to form a shallow trench isolation (STI). A first gate structure 22 and a second gate structure 24 are formed on part of the first fin-shaped structure 12 and the second fin-shaped structure 14 respectively. Each of the first gate structure 22 and the second gate structure 24 includes a gate electrode 26 and a hard mask 28 disposed on the gate electrode 26, and a plurality of dummy gates 30 could be formed selectively adjacent to the first gate structure 22 and the second gate structure 24. In the transistor device formed afterwards, the regions of the fin-shaped structures 12, 14 overlapped by the gate electrodes 26 could be used as a channel for carrier flow.

The formation of the first fin-shaped structure 12 and the second fin-shaped structure 14 could include first forming a patterned mask (not shown) on the substrate, 10, and an etching process is performed to transfer the pattern of the patterned mask to the substrate 10. Next, depending on the structural difference of a tri-gate transistor or dual-gate fin-shaped transistor being fabricated, the patterned mask could be stripped selectively or retained, and deposition, chemical mechanical polishing (CMP), and etching back processes are carried out to form an insulating layer 16 surrounding the bottom of the fin-shaped structures 12, 14. Alternatively, the formation of the first fin-shaped structure 12 and the second fin-shaped structure 14 could also be accomplished by first forming a patterned hard mask (not shown) on the substrate 10, and then performing an epitaxial process on the exposed substrate 10 through the patterned hard mask to grow a semiconductor layer. This semiconductor layer could then be used as the corresponding fin-shaped structures 12, 14. In another fashion, the patterned hard mask could be removed selectively or retained, and deposition, CMP, and then etching back could be used to form an insulating layer 16 to surround the bottom of the fin-shaped structures 12, 14. Moreover, if the substrate 10 is a SOI substrate, a patterned mask could be used to etch a semiconductor layer on the substrate until reaching a bottom oxide layer underneath the semiconductor layer to form the corresponding fin-shaped structures. If this means is chosen the aforementioned steps for fabricating the insulating layer 16 could be eliminated.

Preferably a gate dielectric layer 32 is formed between the gate electrodes 26 and the fin-shaped structures 12, 14. The gate electrodes 26 preferably consist of doped or non-doped polysilicon, but could also be selected from a material consisting silicide of metals. The gate dielectric layer 32 preferably consists of a silicon layer, such as SiO, SiN, or SiON, but could also be selected from dielectric materials having high-k dielectric properties.

Next, as shown in FIG. 2, a first hard mask 34 is formed entirely to cover the first gate structure 22 and the second gate structure 24. According to a preferred embodiment of the present invention, the first hard mask 34 is selected from a group consisting of SiC, SiON, SiN, SiCN, and SiBN, but not limited thereto.

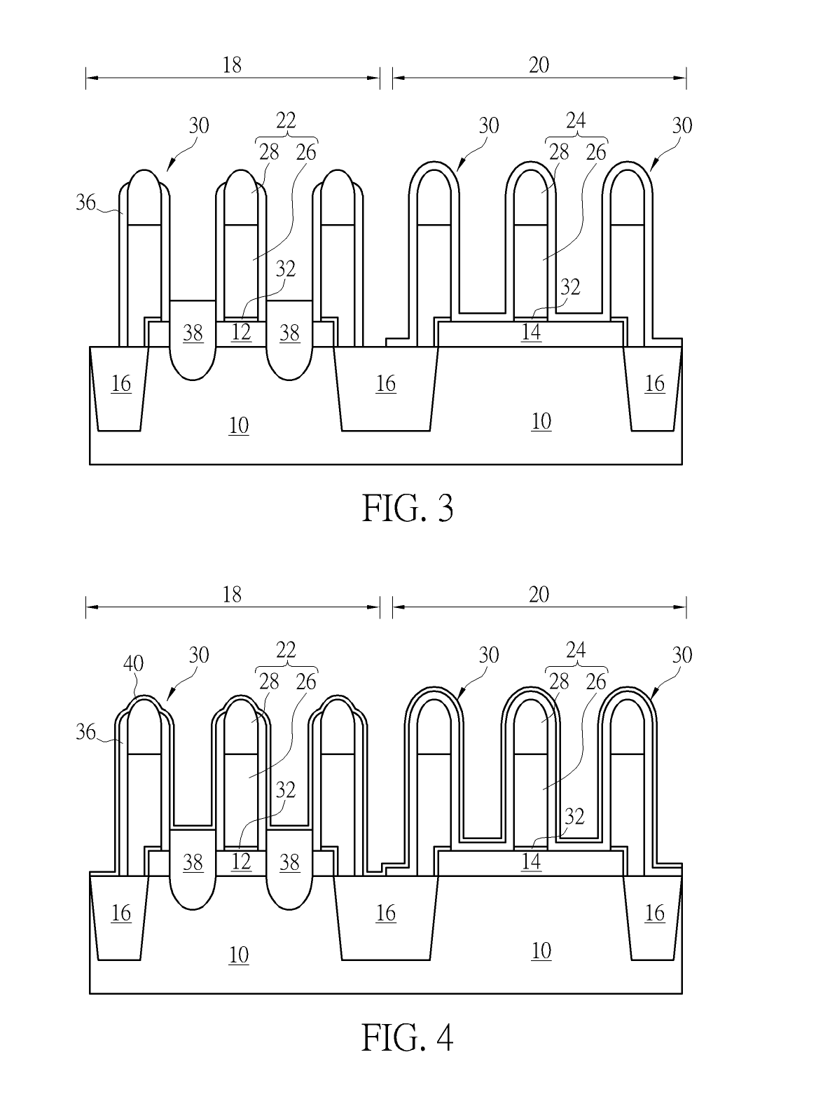

As shown in FIG. 3, a patterned resist (not shown) is formed in the NMOS region 20, and a portion of the first hard mask 34 in the PMOS region 18 is removed by using the patterned resist as a mask to form a first spacer 36 around the first gate structure 22 and a first recess (not shown) in the first fin-shaped structure 12 adjacent to the first gate structure 22. After stripping the patterned resist from the NMOS region 20, a selective epitaxial growth is carried out to form a first epitaxial layer 38 composed of silicon germanium in the first recess.

Next, as shown in FIG. 4, a second hard mask 40 is formed entirely to cover the first gate structure 22 and the second gate structure 24, and part of the first hard mask 34 of the NMOS region 20. According to a preferred embodiment of the present invention, the second hard mask 40 is selected from a group consisting of SiC, SiON, SiN, SiCN, and SiBN, but not limited thereto.

Next, as shown in FIG. 5, a patterned resist (not shown) is formed in the PMOS region 18, and part of or all of the second hard mask 40 in the NMOS region 20 is removed by using the patterned resist as a mask. Therefore, another first spacer 42 is formed around the second gate structure 24 and a second recess (not shown)is formed in the second fin-shaped structure 14 adjacent to the second gate structure 22. Then, the patterned resist is stripped from the PMOS region 18. Afterwards, a selective epitaxial growth is conducted to forma second epitaxial layer 44 composed of silicon phosphorus (SiP) or silicon carbide (SiC) in the second recess.

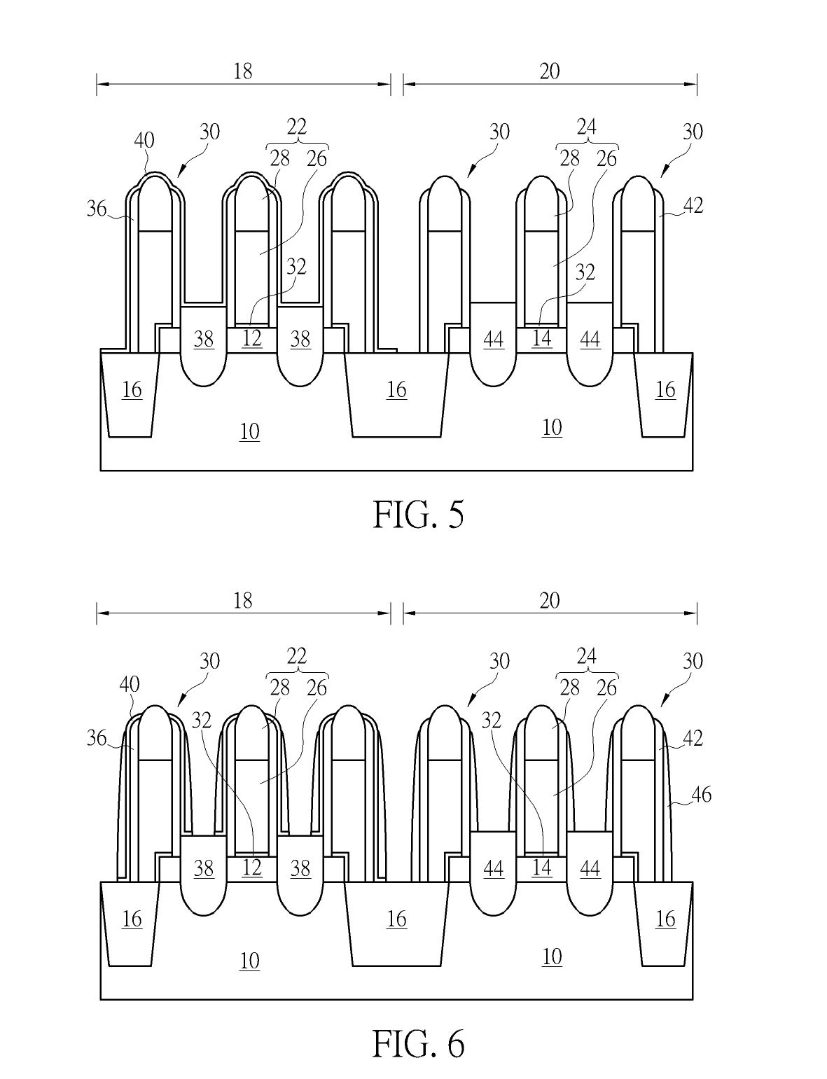

Next, as shown in FIG. 6, a second spacer 46 is formed around the first gate structure 22 and the second gate structure 24. The steps for forming the second spacer 46 could be similar to the aforementioned process for forming the first spacers 36, 42 and the details of which are not described herein for the sake of brevity. It should be noted that even if a second spacer 46 is formed directly on the sidewall of the first spacers 36, 42, the first spacers 36, 42 could also be removed before the formation of the second spacer 46 so that the second spacer 46 would be formed directly on the sidewall of the first and second gate structures 22, 24. This approach is also within the scope of the present invention.

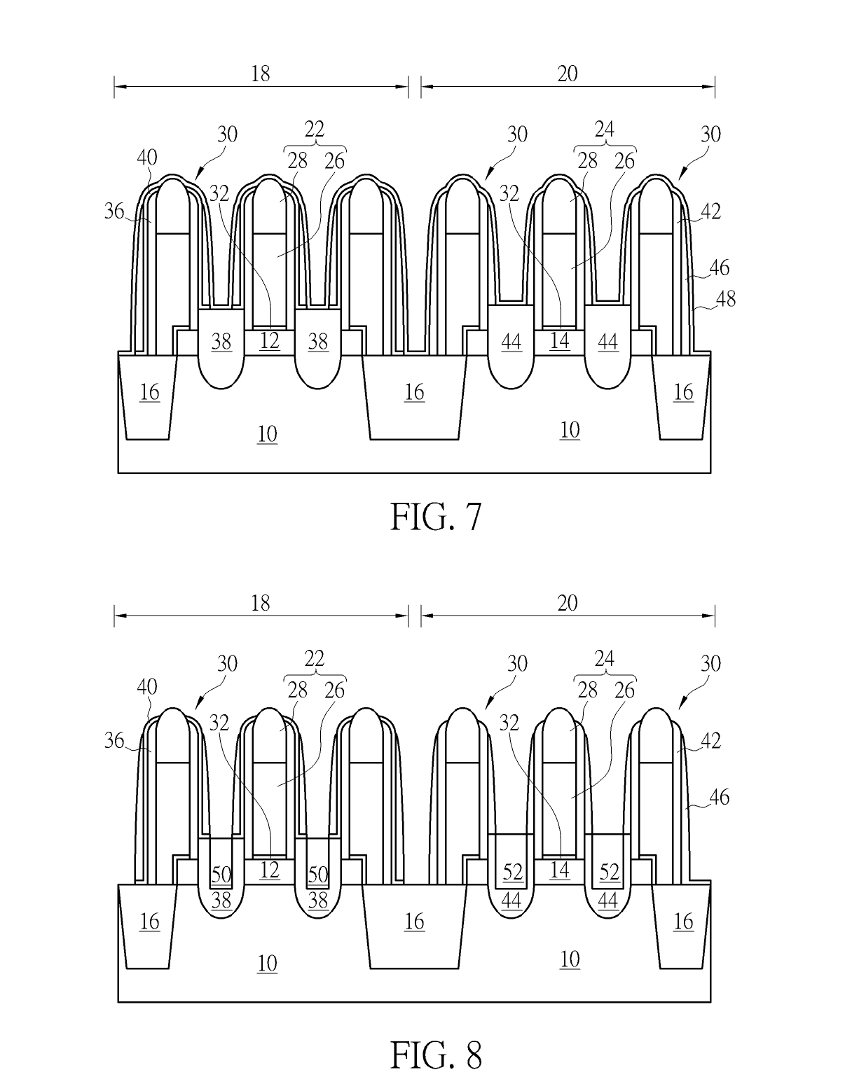

Next, as shown in FIG. 7, an oxide seal 48 is covered on the second spacer 46, the first gate structure 22, and the second gate structure 24. Then, as shown in FIG. 8, an ion implantation is performed to form source/drain regions in the PMOS region 18 and the NMOS region 20. For instance, a patterned resist (not shown) could be covered on the NMOS region 20, and a p-type ion implantation is conducted in the PMOS region 18 to form a source/drain region 50 in the first epitaxial layer 38 adjacent to the first gate structure 22. After stripping the patterned resist from the NMOS region 20, another patterned resist (not shown) is formed on the PMOS region 18 and an n-type ion implantation is performed in the NMOS region 20 to form a source/drain region 52 in the second epitaxial layer 44 adjacent to the second gate structures 24. The patterned resist in the PMOS region 18 is then stripped thereafter.

After forming the source/drain regions 50 and 52, diluted hydrofluoric acid (DHF) is used to remove the oxide seal 48 from the first gate structure 22, the second gate structure 24 and the second spacer 46. Typically, a wet clean through the utilization of HCl is carried out to remove polymers from the surface of the substrate after the source/drain regions 50, 52 are formed and after the patterned resist is stripped. Through the formation of the aforementioned oxide seal 48, the first epitaxial layer 38 and the second epitaxial layer 44 are protected throughout the wet clean process.

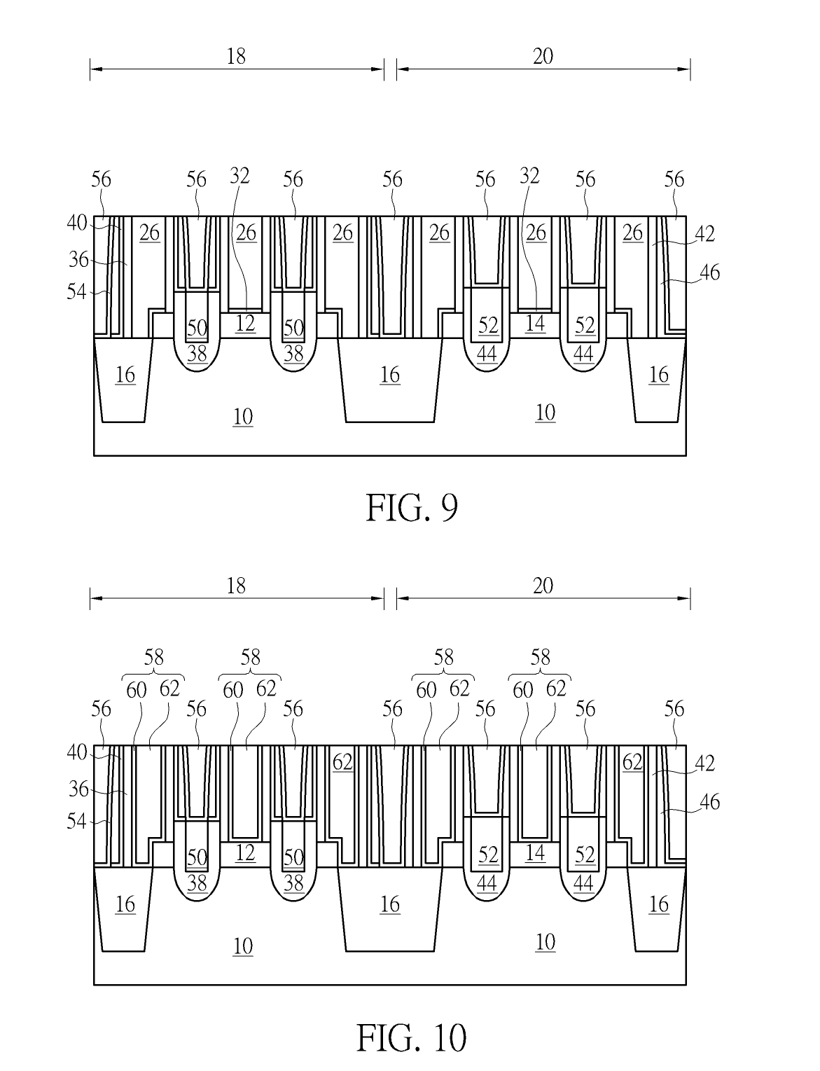

Afterwards, as shown in FIG. 9, a contact etch stop layer (CESL) 54 is deposited on the first gate structure 22, second gate structure 24, and second spacer 46 of the PMOS region 18 and the NMOS region 20. Next, a flowable chemical vapor deposition, FCVD) is carried out to form an interlayer dielectric (ILD) layer 56 on the CESL 54. A planarizing process, such as a chemical mechanical polishing (CMP) process is then performed to partially remove the ILD layer 56, CESL 54, and hard mask 28 so that the top of the gate electrode 26 made of polysilicon within the first gate structure 22, the second gate structure 24 and the dummy gates is exposed and substantially even with the surface of the ILD layer 56. Alternatively, another approach could be utilized by first performing a CMP process to partially remove the ILD layer 56 until reaching the CESL 54, and then using a dry etching process to partially remove the ILD layer 56, the CESL 54, and the hard mask 28 for exposing the top of the gate electrode 26, which is also within the scope of the present invention.

Next, as shown in FIG. 10, a replacement metal gate (RMG) process is conducted to form a metal gate 58 in each of the PMOS region 18 and the NMOS region 20, in which each metal gate 58 includes a high-k dielectric layer 60 and a conductive layer 62.

According to a preferred embodiment of the present invention, the RMG process could be carried out by first performing a selective dry etching or wet etching process, such as using etchants including ammonium hydroxide (NH₄OH) or tetramethylammonium hydroxide (TMAH) to remove the polysilicon layer from the first gate structure 22 and the second gate structure 24 without etching the ILD layer 56 for forming a recess (not shown) in each transistor region 18 and 20. Next, a high-k dielectric layer 60 and an adequate conductive layer 62 are deposited into the recess, and the layers 60 and 62 are planarized to form a metal gate 50 in each PMOS region 18 and NMOS region 20.

According to a preferred embodiment of the present invention, RMG process includes approaches such as gate first process, high-k first process from gate last process, high-k last process from gate last process, or polysilicon gate process. The present embodiment is preferably accomplished by the employment of high-k last process from the gate last process, hence the high-k dielectric layer 60 is preferably has a “U-shaped” cross section, and the high-k dielectric layer 60 could be made of dielectric materials having a dielectric constant (k value) larger than 4. The material of the high-k dielectric layer 60 may be selected from hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate (SrBi₂Ta₂O₉, SBT), lead zirconate titanate (PbZrₓTi₁₋ₓO₃, PZT), barium strontium titanate (BaₓSr₁₋ₓTiO₃, BST) or a combination thereof.

The high-k dielectric layer 60 can be formed through an atomic layer deposition (ALD) process or a metal-organic chemical vapor deposition (MOCVD) process, but is not limited thereto. Furthermore, a dielectric layer (not shown) such as a silicon oxide layer can be selectively formed between the substrate 10 and the high-k dielectric layer 60. The conductive layers 62 may consist one or more metal layers such as a work function metal layer (not shown), a barrier layer (not shown) and a low-resistance metal layer (not shown). The work function metal layer is formed for tuning the work function of the later formed metal gates 58 to be appropriate in an NMOS or a PMOS. For an NMOS transistor, the work function metal layer 62 having a work function ranging between 3.9 eV and 4.3 eV may include titanium aluminide (TiAl), zirconium aluminide (ZrAl), tungsten aluminide (WAl), tantalum aluminide (TaAl), hafnium aluminide (HfAl), or titanium aluminum carbide (TiAlC), but it is not limited thereto. For a PMOS transistor, the work function metal layer 62 having a work function ranging between 4.8 eV and 5.2 eV may include titanium nitride (TiN), tantalum nitride (TaN), tantalum carbide (TaC), but it is not limited thereto. The material of the barrier layer may include titanium (Ti), titanium nitride (TiN), tantalum (Ta) or tantalum nitride (TaN). Furthermore, the material of the low-resistance metal layer may include tungsten (W), copper (Cu), aluminum (Al), titanium aluminum (TiAl), cobalt tungsten phosphide (CoWP) or any combination thereof.

Next, as shown in FIG. 11, a cap film 64 is covered on the metal gates 58, in which the cap film 64 is preferably composed of oxides, but not limited thereto. A one-photo-one-etching (1P1E) or two-photo-two-etching (2P2E) process is then conducted to form a plurality of openings, such as contact holes 66 in the cap film 64 and the ILD layer 56 to expose the first epitaxial layer 38 and the second epitaxial layer 44.

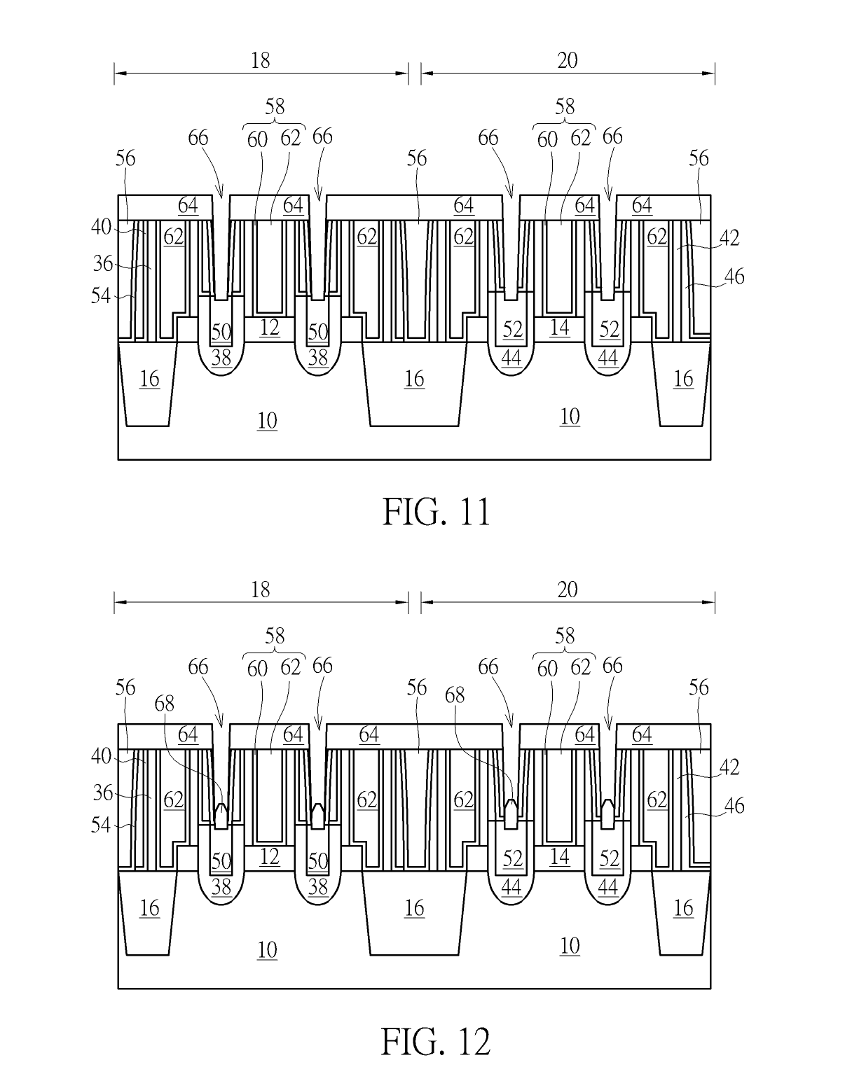

Next, as shown in FIG. 12, a germanium cap 68 is formed on top of the first epitaxial layer 38 and the second epitaxial layer 44 within each contact hole 66. The composition of germanium cap 68 may at least consist of silicon and germanium. Also, it may further consist of boron. According to this embodiment, the germanium cap 68 has a germanium concentration in excess of 50 atomic % or even in excess of 90 atomic % and has a boron concentration in excess of 1E20 cm⁻³ near the top surface of the germanium cap 68. Preferably, the boron concentration in the germanium cap 68 is gradually increased from the bottom to the top of the germanium cap 68. In this way, the external resistance of the FinFET may be reduced. In addition, additional silicon caps (not shown) may be formed on top of the first epitaxial layer 38 and the second epitaxial layer 44 before the formation of the germanium cap 68. For example, silicon caps may be formed before the deposition of the ILD layer 56 or formed after the formation of the contact holes 66. The silicon cap disposed between the germanium cap 68 and the fin-shaped structure 12 maybe used as a stress buffer layer. It should be noted that both the germanium cap 68 and the silicon cap are disposed above the surface of the substrate 10, and the thickness of the germanium cap is preferably thicker than the thickness of the silicon cap, and more preferably 3 times thicker than the thickness of the silicon cap.

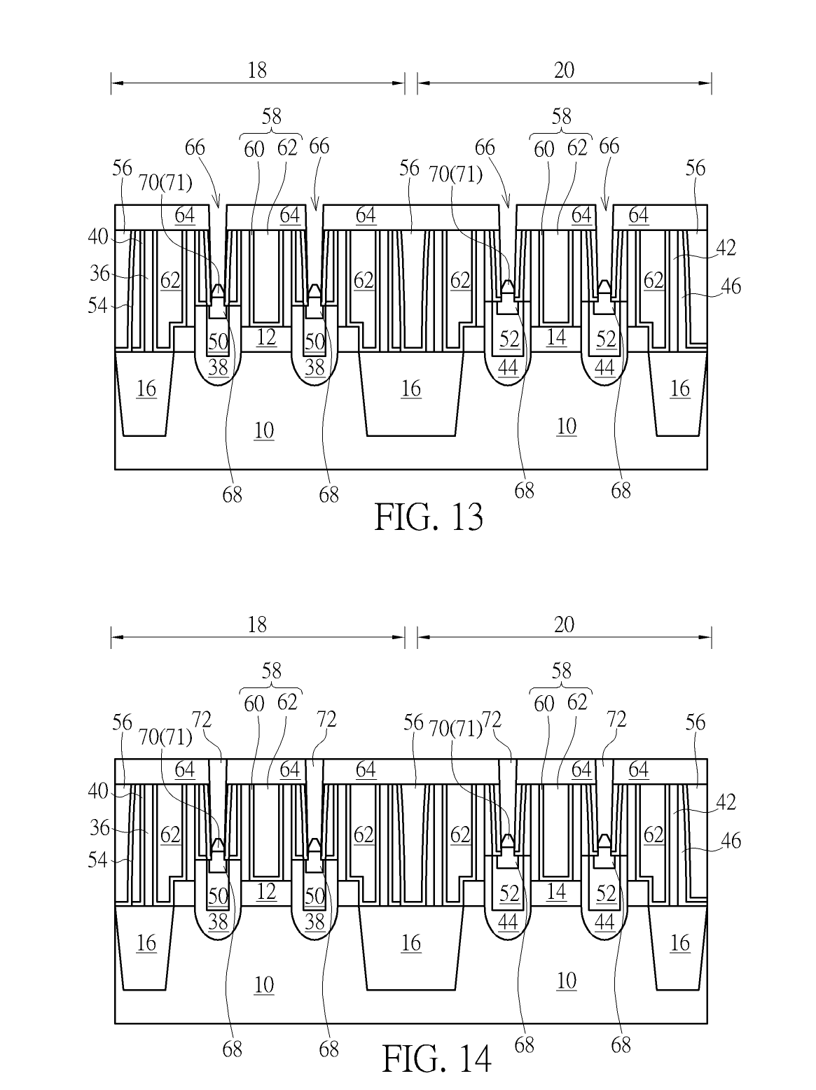

Next, as shown in FIG. 13, a salicide process is performed, such as by first depositing a metal layer (not shown) consisting of cobalt (Co), titanium (Ti), nickel (Ni), or nickel platinum alloy (NiPt) into the contact holes 66. Preferably, a protection cap (not shown) such as titanium nitride (TiN) may be further deposited on the metal layer to prevent unnecessary contamination. A rapid thermal anneal (RTA) process is then conducted to react metal atoms of the metal layer with silicon atoms and/or germanium atoms of the germanium cap 68 to produce a silicide layer 70 and/or a germanide layer 71. According to a preferred embodiment of the present invention, the silicide layer 70 and/or the germanide layer 71 may only be formed at the top surface of the germanium caps 68. That is, portions of the germanium cap 68 still remain at the bottom of each contact hole 66 during the salicide process. However, the germanium cap 68 may also be consumed entirely through the salicide process so that the resulting silicide and/or germanide layers 70 and 71 are grown directly on the two epitaxial layers. Finally, the unreacted metal layer and the protection cap are removed.

Next, as shown in FIG. 14, contact plugs 72 are further formed in the contact holes 66. The steps of forming the contact plugs 72 are described below. First, a barrier/adhesive layer (not shown), a seed layer (not shown) and a conductive layer (not shown) are sequentially formed to cover the cap film 64 and fill the contact holes 66, in which the barrier/adhesive layer are formed conformally along the surfaces of the contact holes 66, and the conductive layer is filled completely into the contact holes 66. The barrier/adhesive layer could be used for preventing metal elements of the conductive layer from diffusing into the neighboring cap film 64, and also increasing the adhesiveness between the conductive layer and the cap film 64. The barrier/adhesive layer may consist of tantalum (Ta), titanium (Ti), titanium nitride (TiN) or tantalum nitride (TaN), tungsten nitride (WN) or a suitable combination of metal layers such as Ti/TiN, but is not limited thereto. A material of the seed layer is preferably the same as a material of the conductive layer, and a material of the conductive layer may include a variety of low-resistance metal materials, such as aluminum (Al), titanium (Ti), tantalum (Ta), tungsten (W), niobium (Nb), molybdenum (Mo), copper (Cu) or the like, preferably tungsten or copper, and more preferably tungsten, which can form suitable Ohmic contact between the conductive layer and the metal silicide layer 70 or between the conductive layer and the source/drain regions 50, 52 underneath. Then, a planarization step, such as a chemical mechanical polish (CMP) process or an etching back process or combination thereof, can be performed to remove the barrier/adhesive layer, the seed layer and the conductive layer outside the contact holes 66, so that a top surface of a remaining conductive layer and the top surface of the cap film 64 are coplanar, thereby forming a plurality of contact plugs 72 and completing the fabrication of a FinFET according to a preferred embodiment of the present invention.

Overall, the germanium caps with the boron concentration in excess of 1E20 cm⁻³ near their top surfaces are formed on the source/drain regions 50 and 52 according to the embodiments of the present invention, and the external resistance of the FinFETs is further reduced accordingly. In addition, the timing for forming the germanium cap is after the formation of contact holes and before the formation of silicide layers. By forming the germanium cap at this time interval, issues such as bumps being formed on the surface of the polysilicon gate electrode could be avoided and drawbacks including encroachment and nickel silicide piping caused during salicide process could also be prevented effectively.

Those skilled in the art will readily observe that numerous modifications and alterations of the device and method may be made while retaining the teachings of the invention. Accordingly, the above disclosure should be construed as limited only by the metes and bounds of the appended claims.

1. A fin-shaped field-effect transistor (FinFET), comprising:
a fin-shaped structure disposed on a substrate;
a gate structure covering a portion of the fin-shaped structure;
an epitaxial layer disposed on the fin-shaped structure adjacent to the gate structure;
an interlayer dielectric layer covering the gate structure and the epitaxial layer;
an opening in the interlayer dielectric layer;
a germanium cap at the bottom of the opening, wherein the germanium cap has a germanium concentration in excess of 50 atomic %;
a silicon cap disposed in the opening and between the germanium cap and the fin-shaped structure; and
a contact plug disposed on the germanium cap in the opening.

2. (canceled)

3. The FinFET of claim 1, wherein a thickness of germanium cap is thicker than a thickness of the silicon cap.

4. The FinFET of claim 1, wherein a thickness of the germanium cap is 3 times thicker than a thickness of the silicon cap.

5. The FinFET of claim 1, wherein the germanium cap and the silicon cap are disposed above the surface of the substrate.

6. The FinFET of claim 1, wherein the germanium cap has a germanium concentration in excess of 90 atomic %.

7. The FinFET of claim 1, wherein the silicon cap has a germanium concentration less than a germanium concentration of the germanium cap.

8. The FinFET of claim 1, further comprising a metal germanide or a metal silicide disposed between the contact plug and the germanium cap.

9. The FinFET of claim 8, wherein the metal germanide or the metal silicide are disposed on a top surface of the germanium cap.

10. The FinFET of claim 1, wherein the germanium cap is a boron-doped germanium cap, and a boron concentration near a top surface of the germanium cap is in excess of 1E20 cm⁻³.

11. The FinFET of claim 10, wherein a boron concentration of the germanium cap is gradually increased from the bottom of the germanium cap to the top of the germanium cap.

12. The FinFET of claim 1, wherein the contact plug comprises tungsten.

13. A method for fabricating a fin-shaped field-effect transistor (FinFET), comprising:
providing a substrate;
forming a fin-shaped structure on the substrate;
forming a gate structure on the fin-shaped structure;
forming an epitaxial layer in the fin-shaped structure adjacent to the gate structure;
forming an interlayer dielectric layer on the gate structure and the epitaxial layer;
forming an opening in the interlayer dielectric layer;
forming a germanium cap at the bottom of the opening, wherein the germanium cap has a germanium concentration in excess of 50 atomic %;
forming a silicon cap layer on the epitaxial layer between the steps of forming the opening and forming the germanium cap; and
forming a contact plug on the germanium cap in the opening.

14. (canceled)

15. The method for fabricating the FinFET of claim 13, wherein the silicon cap has a germanium concentration less than a germanium concentration of the germanium cap.

16. (canceled)

17. The method for fabricating the FinFET of claim 13, further comprising forming a metal germanide or a metal silicide at a top surface of the germanium cap.

18. The method for fabricating the FinFET of claim 13, further comprising:
depositing a metal layer on the germanium cap; and
reacting the metal layer with the germanium cap so as to produce a metal germanide or a metal silicide.

19. The method for fabricating the FinFET of claim 13, wherein the germanium cap is a boron-doped germanium cap, and a boron concentration near a top surface of the germanium cap is in excess of 1E20 cm⁻³.

20. The method for fabricating the FinFET of claim 19, wherein a boron concentration of the germanium cap is gradually increased from the bottom of the germanium cap to the top of the germanium cap.
